(19) United States
(12) Patent Application Publication
(10) Pub. No.: US 2026/0169074 A1
(43) Pub. Date: Jun. 18, 2026

(54) CHARGING CONTROL DEVICE, ENERGY STORAGE SYSTEM, REMAINING CHARGING TIME NOTIFICATION METHOD, AND REMAINING CHARGING TIME NOTIFICATION PROGRAM

(71) Applicant: FDK CORPORATION, Minato-ku, Tokyo (JP)

(72) Inventors: Shun Mochizuki, Tokyo (JP); Katsuhiko Tamaki, Tokyo (JP); Yasuyuki Katsube, Tokyo (JP)

(21) Appl. No.: 19/119,791

(22) PCT Filed: Oct. 19, 2023
(86) PCT No.: PCT/JP2023/037895

§ 371 Date: Apr. 10, 2025

(30) Foreign Application Priority Data
Oct. 19, 2022 (JP) 2022-167597

(51) Int. Cl. G01R 31/36; G01R 31/367; G01R 31/374; G01R 31/3842; G01R 31/396; H01M 10/44

(52) U.S. Cl. CPC G01R 31/3646; G01R 31/367; G01R 31/374; G01R 31/3842; G01R 31/396; H01M 10/441

(57) ABSTRACT

The purpose of the present invention is to allow users to sooner understand a more accurate time required in order for charging to complete. This charging control device comprises: a processing unit that, during charging of a power storage device, corrects a calculated value of remaining charging time calculated at the start of charging of the power storage device, and, at the start of charging, acquires information indicating a correction timing at which the calculated value of the remaining charging time is corrected; and a reporting unit that reports the correction timing at the start of charging and reports the correction value of the calculated value of the remaining charging time during charging.

### TECHNICAL FIELD

The present invention relates to a charging control device, an energy storage system, a remaining charging time notification method, and a remaining charging time notification program.

### BACKGROUND ART

Patent Literature (hereinafter, referred to as PTL) 1 discloses a battery bank unit (hereinafter also referred to as an “energy storage system”) that discharges to a load device connected to an external power source when the external power source becomes unable to supply power due to a power outage. The battery bank unit includes plurality of battery banks (hereinafter also referred to as “energy storage devices”). The plurality of battery banks are each composed of plurality of secondary batteries and are connected in parallel to each other. The plurality of battery banks are charged during normal times by power from an external power source.

A battery bank unit is configured such that plurality of battery banks are charged in sequence, and a battery bank that is not being charged can discharge to the load device. This allows the battery bank unit to discharge to the load device even while the battery bank unit is being charged.

### CITATION LIST

### Patent Literature

### PTL 1

Japanese Patent Application Laid-Open No. 2016-10250

### SUMMARY OF INVENTION

### Technical Problem

For example, in the management of a load device, there is a demand for more accurate and earlier determination of the time required for completely charging the battery bank unit (hereinafter also referred to as “remaining charging time”) while the battery bank unit is being charged.

An object of the present invention is to provide a charging control device, an energy storage system, a remaining charging time notification method, and a remaining charging time notification program that allow a user to know more accurately and earlier the time required for charging to be completed.

### Solution to Problem

One aspect of the charging control device according to the present invention includes:
a processor that corrects, during an execution of charging of an energy storage device, a calculated value of a remaining charging time calculated at a start of the charging of the energy storage device, and acquires, at the start of the charging, information indicating correction timing at which the calculated value of the remaining charging time is corrected; and
a notification section that notifies, at the start of the charging, the correction timing, and notifies, during the execution of the charging, a correction value for the calculated value of the remaining charging time.

One aspect of the energy storage system according to the present invention includes:
the above charging control device; and
the above energy storage device.

One aspect of the remaining charging time notification method according to the present invention is as follows:
a remaining charging time notification method to be executed in a charging control device that, during an execution of charging of an energy storage device, corrects a calculated value of a remaining charging time calculated at a start of the charging of the energy storage device and notifies the corrected calculated value, the method including:
acquiring, at the start of the charging, information indicating correction timing at which the calculated value of the remaining charging time is corrected; and
notifying, at the start of the charging, the correction timing.

One aspect of the remaining charging time notification program according to the present invention causes a computer to execute the above remaining charging time notification method.

### Advantageous Effects of Invention

According to the present invention, it is possible to allow a user to know more accurately and earlier the time required for charging to be completed.

### BRIEF DESCRIPTION OF DRAWINGS

FIG. 1 is a schematic diagram illustrating a battery bank unit according to one embodiment of the present invention;

FIG. 2 is a block diagram of the battery bank unit according to one embodiment of the present invention;

FIG. 3 illustrates a first table stored in a storage of a control device in the battery bank unit according to one embodiment of the present invention;

FIG. 4 is a flowchart to be executed by the control device illustrated in FIG. 3 when the battery bank unit is charged;

FIG. 5 is a time chart when the flowchart of FIG. 4 is executed;

FIG. 6 is a flowchart to be executed by the control device illustrated in FIG. 3 when a remaining charging time is calculated;

FIG. 7 illustrates an example of a notification screen displayed on a terminal device of a user based on a notification from the battery bank unit according to one embodiment of the present invention; and

FIG. 8 illustrates a second table stored in a storage of a control device in a battery bank unit according to a variation of one embodiment of the present invention.

### DESCRIPTION OF EMBODIMENTS

Hereinafter, embodiments of the present invention will be described in detail with reference to the drawings.

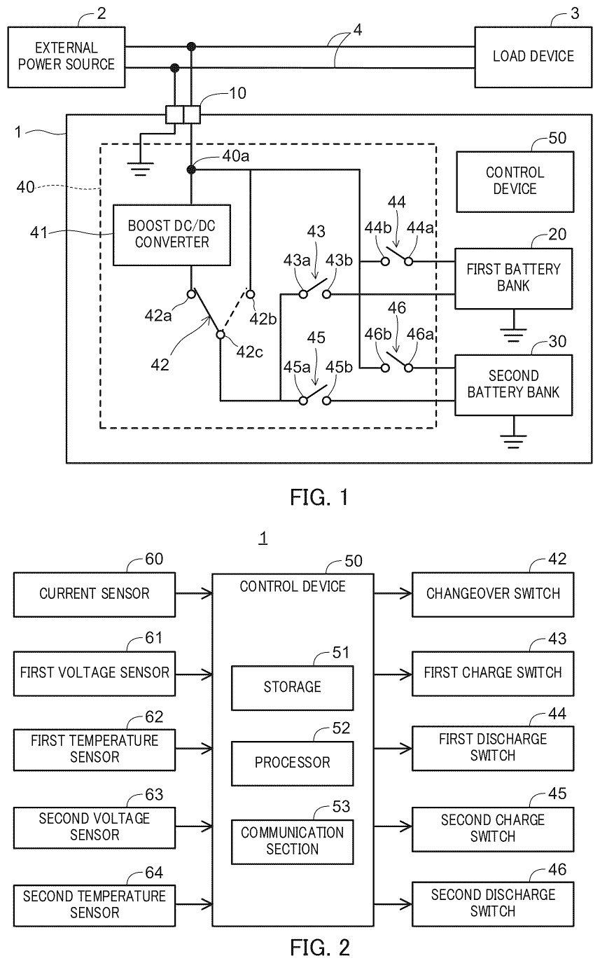

FIG. 1 is a schematic diagram of battery bank unit 1 of the present embodiment. Battery bank unit 1 supplies power to load device 3 connected to external power source 2 when external power source 2 experiences a power outage. In addition, battery bank unit 1 is charged by the power from external power source 2. Battery bank unit 1 is an example of an energy storage system in the present invention.

External power source 2 is, for example, a device that converts commercial AC power into DC power and outputs the DC power. Load device 3 is a device (e.g., a server device) that operates on DC power.

As illustrated in FIG. 1, battery bank unit 1 includes input/output terminal 10, first and second battery banks 20 and 30, charge/discharge circuit 40, and control device 50. The combination of first and second battery banks 20 and 30 is an example of an energy storage device in the present invention, and control device 50 is an example of a charging control device in the present invention.

Input/output terminal 10 is connected to power line 4 that supplies power from external power source 2 to load device 3.

First and second battery banks 20 and 30 are each composed of plurality of secondary batteries (e.g., nickel-metal hydride secondary batteries) connected in series, for example. Not only the nickel-metal hydride secondary batteries, the secondary battery may be any secondary battery such as a lithium-ion secondary battery. First and second battery banks 20 and 30 are configured similarly to each other. First and second battery banks 20 and 30 are connected in parallel to each other.

Charge/discharge circuit 40 functions as a circuit for charging and discharging first and second battery banks 20 and 30 via input/output terminal 10. Charge/discharge circuit 40 includes boost DC/DC converter 41, changeover switch 42, first charge switch 43, first discharge switch 44, second charge switch 45, and second discharge switch 46.

Boost DC/DC converter 41 is a power conversion device that boosts the power supplied from external power source 2 and outputs the power.

Changeover switch 42 switches the voltage values applied to first and second battery banks 20 and 30. In changeover switch 42, first terminal 42a is connected to output terminal of boost DC/DC converter 41, and second terminal 42b is connected to input/output terminal 10. In addition, third terminal 42c is connected to first and second battery banks 20 and 30 via first and second charge switches 43 and 45.

When changeover switch 42 is in the on state, first terminal 42a and third terminal 42c are connected to each other, and the power output from boost DC/DC converter 41 is supplied to first and second battery banks 20 and 30 via first and second charge switches 43 and 45. On the other hand, when changeover switch 42 is in the off state, second terminal 42b and third terminal 42c are connected to each other, and the power output from external power source 2 is supplied to first and second battery banks 20 and 30 via first and second charge switches 43 and 45.

First charge switch 43 allows charging of first battery bank 20 when in the on state and does not allow the charging of first battery bank 20 when in the off state. In first charge switch 43, first terminal 43a is connected to third terminal 42c of changeover switch 42, and second terminal 43b is connected to the positive electrode of first battery bank 20. The negative electrode of first battery bank 20 is connected to the ground.

First discharge switch 44 allows discharging of first battery bank 20 when in the on state and does not allow the discharging of first battery bank 20 when in the off state. In first discharge switch 44, first terminal 44a is connected to the positive electrode of first battery bank 20, and second terminal 44b is connected to input/output terminal 10.

Second charge switch 45 allows charging of second battery bank 30 when in the on state and does not allow the charging when in the off state. In second charge switch 45, first terminal 45a is connected to third terminal 42c of changeover switch 42, and second terminal 45b is connected to the positive electrode of second battery bank 30. The negative electrode of second battery bank 30 is connected to the ground.

Second discharge switch 46 allows discharging of second battery bank 30 when in the on state and does not allow the discharging of second battery bank 30 when in the off state. In second discharge switch 46, first terminal 46a is connected to the positive electrode of second battery bank 30, and second terminal 46b is connected to input/output terminal 10.

FIG. 2 is a block diagram of battery bank unit 1. As illustrated in FIG. 2, battery bank unit 1 further includes current sensor 60, first voltage sensor 61, first temperature sensor 62, second voltage sensor 63, and second temperature sensor 64.

Current sensor 60 detects the current value flowing in from or out to power line 4 via input/output terminal 10. To be more specific, current sensor 60 detects the current value between input/output terminal 10 and the connection point 40a of charge/discharge circuit 40. First voltage sensor 61 detects the voltage value of first battery bank 20. First temperature sensor 62 detects the temperature of first battery bank 20.

Second voltage sensor 63 detects the voltage value of second battery bank 30. Second temperature sensor 64 detects the temperature of second battery bank 30. Current sensor 60, first voltage sensor 61, first temperature sensor 62, second voltage sensor 63, and second temperature sensor 64 each transmit the detected values to control device 50.

In addition, battery bank unit 1 further includes a third voltage sensor (not illustrated) for detecting a power source voltage value, namely the voltage value of external power source 2. Control device 50 detects a power outage of external power source 2 based on the power source voltage value detected by the third voltage sensor.

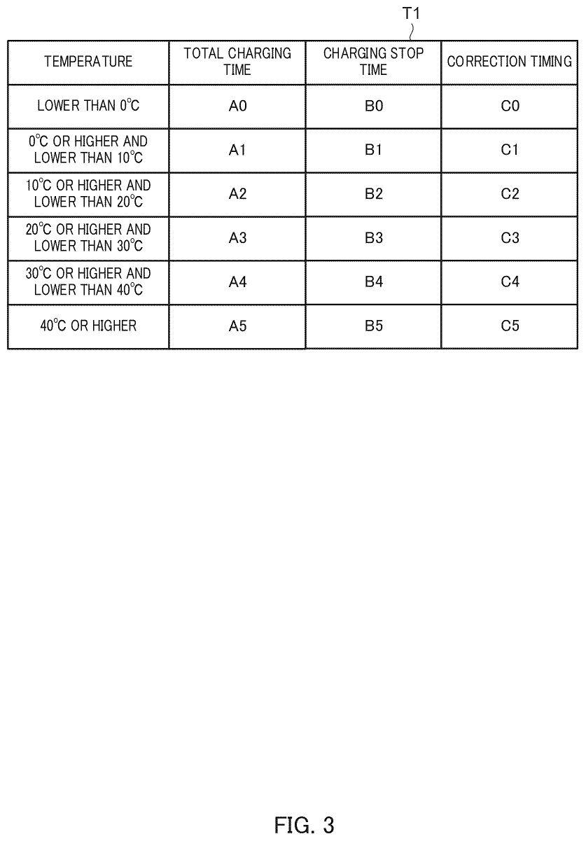

Control device 50 controls the charging and discharging of battery bank unit 1 by controlling the state of each of switches 42 to 46. Control device 50 includes storage 51, processor 52, and communication section 53, and is realized by a computer, for example. Processor 52 is realized by a central processor (CPU), for example. Storage 21 includes a storage device realized by a hard disk drive (HDD), for example, and a memory device realized by random access memory (RAM), for example. Storage 51 stores first table T1 illustrated in FIG. 3. Communication section 53 is realized by communication equipment capable of communicating with a terminal device of a user (not illustrated) located remotely via a wired or wireless communication network.

Processor 52 reads various control programs or instructions to implement functions of battery bank unit 1 and data and the like related to the programs or instructions (hereinafter simply referred to as “programs and the like”) from the storage device, stores the programs or instructions in the memory device, and executes various control programs or instructions while using the data and the like. In the present embodiment, the data and the like include first table T1, and the programs and the like include a remaining charging time notification program configured to cause a computer to implement a remaining charging time notification method.

The programs and the like may be stored in a removable storage medium such as flash memory. In this case, control device 50 is configured to allow the removable storage medium to be attached and detached, and reads the programs and the like from the storage medium. In addition, communication section 53 may download the programs and the like from an external source via a communication network.

The storage device, memory device, and removable storage medium described above are examples of a non-transitory computer-readable storage medium.

First table T1 is a table that is referred to by control device 50 when control device 50 calculates the remaining charging time (hereinafter simply referred to as “remaining time”), which is the time required to complete the charging of battery bank unit 1 as described below. In first table T1, the temperature, total charging time, charging stop time, and correction timing are associated with each other. In first table T1, the temperature is divided into six temperature zones in total, and between 0° C. and 40° C., there are four zones each including a range of 10° C. It goes without saying that the temperature range and the number of temperature zones are not limited to those illustrated in FIG. 3. Details of the total charging time, charging stop time, and correction timing will be described below. The temperature zone is an example of a reference value for temperature in the present invention.

In addition, control device 50 calculates the state of charge (SOC), namely a charging state, of battery bank unit 1 by using a known method based on the current value detected by current sensor 60. The SOC of battery bank unit 1 is the charge rate (%) corresponding to the total charge amount, which is the sum of the charge amounts of first and second battery banks 20 and 30.

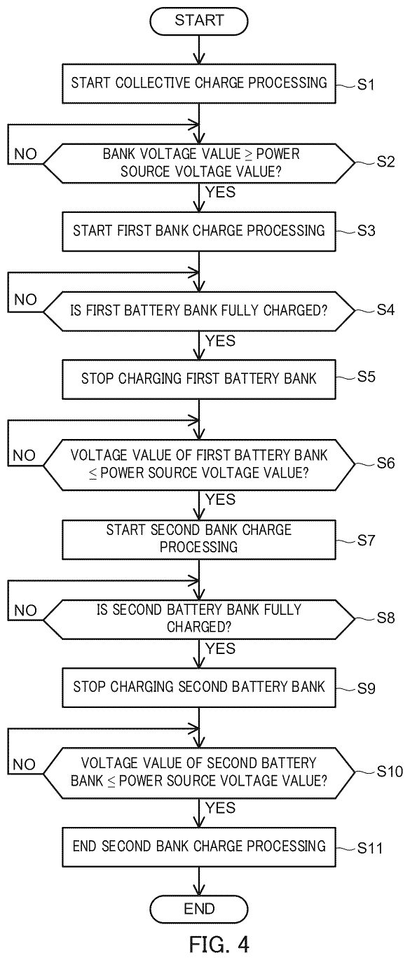

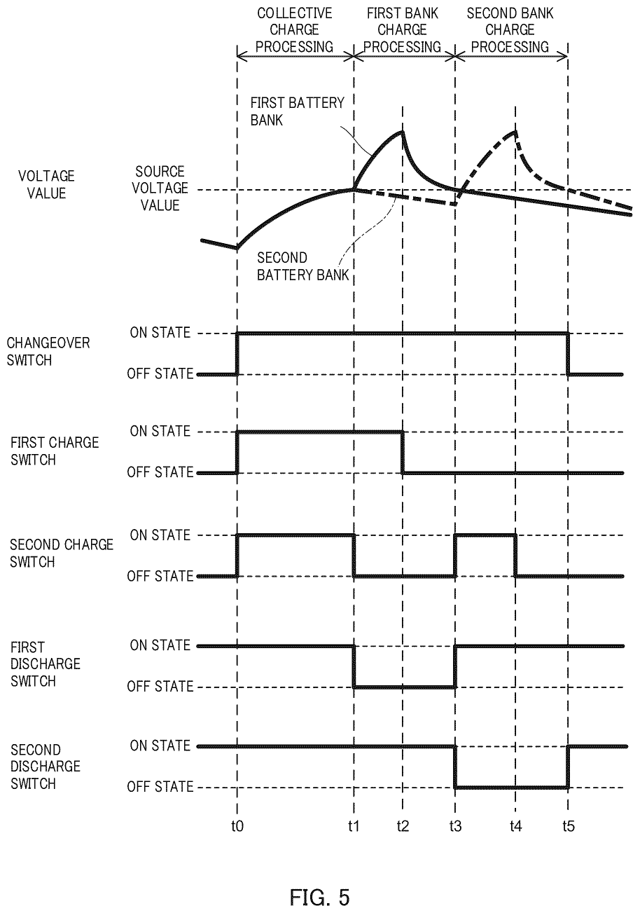

Next, the charging control of battery bank unit 1 executed by control device 50 will be described with reference to the flowchart in FIG. 4 and the time chart in FIG. 5.

In the state in which charging control has not started, changeover switch 42 and first and second charge switches 43 and 45 are each in the off state, and first and second discharge switches 44 and 46 are each in the on state, allowing the discharging of first and second battery banks 20 and 30. In addition, as described above, first and second battery banks 20 and 30 are configured similarly to each other and are connected in parallel. Therefore, the voltage values of first and second battery banks 20 and 30 are approximately equal, and the charge amounts of first and second battery banks 20 and 30 are also approximately equal. Therefore, the SOC of battery bank unit 1 is approximately equal to each of the SOC of first and second battery banks 20 and 30.

Control device 50 starts charging control when the control device detects the connection to external power source 2 or the end of a power outage of external power source 2 based on the detected value of the third voltage sensor.

Control device 50 starts the collective charge processing in S1. The collective charge processing is a process of charging first and second battery banks 20 and 30 collectively. To be more specific, from a state in which changeover switch 42 and first and second charge switches 43 and 45 are in the off state and first and second discharge switches 44 and 46 are in the on states, control device 50 switches changeover switch 42 and first and second charging switches 43 and 45 to the on states (time to), as illustrated in FIG. 5.

First and second discharge switches 44 and 46 remain in the on state. This allows battery bank unit 1 to discharge to load device 3 even when external power source 2 experiences a power outage during the collective charge processing.

When the collective charge processing is started (time t0), power is supplied from boost DC/DC converter 41 to first and second battery banks 20 and 30, and the voltage values of first and second battery banks 20 and 30 increase.

In FIG. 5, the solid-line voltage value indicates the voltage value of first battery bank 20, and the chain-line voltage value indicates the voltage value of second battery bank 30. Before and during the collective charge processing, the voltage values of first and second battery banks 20 and 30 are approximately equal. That is, the lines indicating the voltage values of first and second battery banks 20 and 30 coincide with each other, resulting in the solid line.

Subsequently, control device 50 determines whether the bank voltage value, which is the voltage value of battery bank unit 1, is equal to or higher than the power source voltage value in S2. To be more specific, the bank voltage value is the average value of the voltage value of first battery bank 20 and the voltage value of second battery bank 30. The bank voltage value may be either one of the voltage values of first and second battery banks 20 and 30. When the bank voltage value is lower than the power source voltage value (NO in S2), the collective charge processing is continued.

On the other hand, when the voltage values of first and second battery banks 20 and 30 increase and the bank voltage value becomes equal to or higher than the power source voltage value (time t1; YES in S2), control device 50 ends the collective charge processing and starts first bank charge processing in S3.

The first bank charge processing is a process of charging only first battery bank 20. In the first bank charge processing, first battery bank 20 is fully charged by a voltage value higher than the power source voltage value. In the first bank charge processing, second battery bank 30 is not charged.

To be more specific, control device 50 switches second charge switch 45 to the off state and first discharge switch 44 to the off state (time t1). As a result, the power of boost DC/DC converter 41 is supplied only to first battery bank 20, and the voltage value of first battery bank 20 further increases to be higher than the power source voltage value. In the first bank charge processing, first discharge switch 44 is in the off state and first battery bank 20 does not discharge. Therefore, it is possible to prevent a voltage value higher than the power source voltage value from being applied to load device 3, thereby preventing failure of load device 3, for example.

On the other hand, the charging of second battery bank 30 is stopped, and the voltage value of second battery bank 30 gradually decreases due to self-discharge. In the first bank charge processing, second discharge switch 46 is in the on state. Therefore, even when external power source 2 experiences a power outage during the first bank charge processing, second battery bank 30 can discharge to load device 3.

Subsequently, control device 50 determines whether first battery bank 20 is fully charged in S4. To be more specific, control device 50 determines whether the detected value of first temperature sensor 62 has reached a predetermined first temperature. The first temperature is the temperature when first battery bank 20 is fully charged. When the detected value of first temperature sensor 62 is lower than the first temperature (NO in S4), control device 50 continues charging only first battery bank 20.

On the other hand, when first battery bank 20 is fully charged and the detected value of first temperature sensor 62 reaches the first temperature (time t2; YES in S4), control device 50 stops charging first battery bank 20 in S5.

To be more specific, control device 50 switches first charge switch 43 to the off state (time t2). As a result, the charging of first battery bank 20 is stopped, and the voltage value of first battery bank 20 gradually decreases due to self-discharge. At this time, the temperature of first battery bank 20 is higher than the temperature of second battery bank 30. Therefore, the drop amount of the voltage value of first battery bank 20 per unit time is larger than the drop amount of the voltage value of second battery bank 30 per unit time.

Subsequently, control device 50 determines whether the voltage value of first battery bank 20 has become equal to or lower than the power source voltage value in S6. When the voltage value of first battery bank 20 is higher than the power source voltage value (NO in S6), control device 50 continues the state in which first and second battery banks 20 and 30 are not charged.

On the other hand, when the voltage value of first battery bank 20 becomes equal to or lower than the power source voltage value (time t3; YES in S6), control device 50 ends the first bank charge processing and starts the second bank charge processing in S7. The second bank charge processing is a process of charging only second battery bank 30. In the second bank charge processing, second battery bank 30 is fully charged by a voltage value higher than the power source voltage value. In the second bank charge processing, first battery bank 20 is not charged.

To be more specific, control device 50 switches second charge switch 45 to the on state, first discharge switch 44 to the on state, and second discharge switch 46 to the off state (time t3). As a result, power is supplied from boost DC/DC converter 41 to only second battery bank 30, and the voltage value of second battery bank 30 increases and exceeds the power source voltage value. In the second bank charge processing, second discharge switch 46 is in the off state, and second battery bank 30 does not discharge. Therefore, it is possible to prevent a voltage value higher than the power source voltage value from being applied to load device 3, thereby preventing failure of load device 3.

On the other hand, the charging of first battery bank 20 remains stopped, and the voltage value of first battery bank 20 gradually decreases due to self-discharge. In the second bank charge processing, first discharge switch 44 is in the on state. Therefore, even when external power source 2 experiences a power outage during the second bank charge processing, first battery bank 20 can discharge to load device 3.

Subsequently, control device 50 determines whether second battery bank 30 is fully charged in S8. To be more specific, control device 50 determines whether the detected value of second temperature sensor 64 has reached a predetermined second temperature. The second temperature is the temperature when second battery bank 30 is fully charged. When the detected value of second temperature sensor 64 is lower than the second temperature (NO in S8), control device 50 continues charging only second battery bank 30. The second temperature may be the same as the first temperature, namely a temperature when first battery bank 20 is fully charged.

On the other hand, when second battery bank 30 is fully charged and the detected value of second temperature sensor 64 reaches the second temperature (time t4; YES in S8), control device 50 stops the charging of second battery bank 30 in S9.

To be more specific, control device 50 switches second charge switch 45 to the off state (time t4). As a result, the charging of second battery bank 30 is stopped, and the voltage value of second battery bank 30 gradually decreases due to self-discharge. At this time, the temperature of second battery bank 30 is higher than that of first battery bank 20. Therefore, the drop amount of the voltage value of second battery bank 30 per unit time is larger than the drop amount of the voltage value of first battery bank 20 per unit time.

Subsequently, control device 50 determines whether the voltage value of second battery bank 30 has become equal to or lower than the power source voltage value in S10. When the voltage value of second battery bank 30 is higher than the power source voltage value (NO in S10), control device 50 continues the state in which first and second battery banks 20 and 30 are not charged.

On the other hand, when the voltage value of second battery bank 30 becomes equal to or lower than the power source voltage value (time t5; YES in S10), control device 50 ends the second bank charge processing in S11. To be more specific, control device 50 switches changeover switch 42 to the off state and second discharge switch 46 to the on state (time t5). As a result, the charging of battery bank unit 1 is ended. Control device 50 specifies the SOC of battery bank unit 1 at the end of the charge of battery bank unit 1 as 100%.

Battery bank unit 1 may include three or more battery banks. When the number of battery banks is m, the m battery banks are collectively charged in the collective charge processing. When the collective charge processing is ended, the m battery banks are charged one by one in sequence, as is the case with the above first and second bank charge processing.

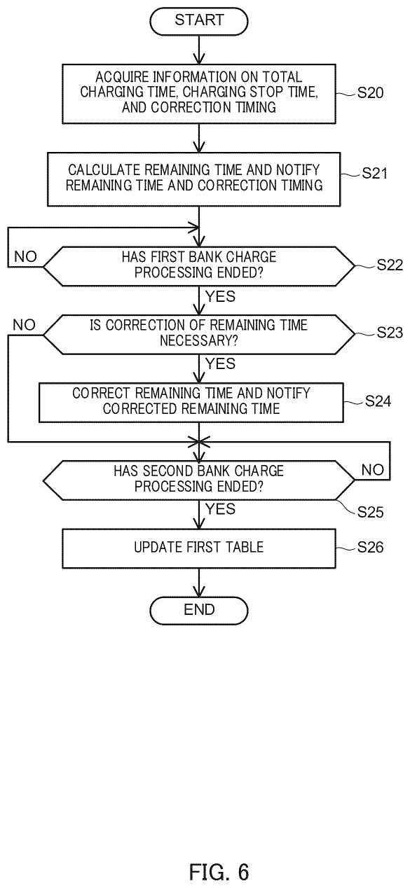

Next, the control for calculating the remaining time executed by control device 50 will be described with reference to the flowchart in FIG. 6. The remaining time is the time required until the charging of battery bank unit 1 is completed. Control device 50 calculates the remaining time during the execution of the above charging control, specifically, between time t0 and t5 in FIG. 5.

In S20, control device 50 reads and acquires information on total charging time, charging stop time, and correction timing associated with the temperature at the start of charging of battery bank unit 1 from first table T1. The temperature of battery bank unit 1 is, for example, the average temperature of first and second battery banks 20 and 30. The temperature of battery bank unit 1 may be the temperature of one of first and second battery banks 20 and 30. The total charging time and charging stop time are used to calculate the remaining time in Equation (1) described below. In addition, the term “at the start of charging” in the present embodiment does not need to be exactly the same time as the start of charging, and may be a time slightly before or after the start of charging.

The total charging time is the time required for the SOC of battery bank unit 1 to reach 100% from the first charge rate (e.g., 0%) at the start of charging, and is determined in advance for each temperature zone by being measured in an experiment and the like, and stored in first table T1. The first charge rate is an arbitrary value used in the experiment and the like to determine the total charging time to be stored in first table T1. In the experiment to determine the total charging time, the collective charge processing and the first and second bank charge processing are performed using battery bank unit 1 in a state in which the SOC is the first charge rate, and the time required for the SOC of battery bank unit 1 to reach 100% from the first charge rate is measured as the total charging time.

The charging stop time is the time corresponding to the time from the stop of charging of first battery bank 20 to the start of charging of second battery bank 30 (i.e., the time from time t2 to time t3 in FIG. 5), and is determined in advance for each temperature zone by being measured in experiment and the like, and stored in first table T1. In the experiment to determine the total charging time described above, the time during which the charging of the battery bank is stopped during the charging of battery bank unit 1 is measured as the charging stop time.

At the start of charging control, for example, when the temperature of battery bank unit 1 is 25° C., control device 50 acquires the total charging time “A3” and the charging stop time “B3” corresponding to the temperature “20° C. or higher and lower than 30° C.” from first table T1 in FIG. 3.

Subsequently, control device 50 calculates the remaining time in S21. To be more specific, control device 50 calculates a remaining time at the start of charging, which is the remaining time when the charging starts, by using Equation (1).

$$( Equation 1 )$$

$$Remaining time at the start of charging = m \times Ts + ( Tt - m \times Ts ) \times ( 100 - So ) / ( 100 - α ) \qquad ( 1 )$$

In Equation (1), m is the number of battery banks. In the present embodiment, m=2. Ts and Tt are the charging stop time and total charging time acquired from first table T1. So (%) is the SOC of battery bank unit 1 at the start of charging control (time t0). Here, α (%) is the first charge rate, which is the SOC of the battery bank unit at the start of the experiment to determine the total charging time stored in first table T1.

So may be the SOC of one of first and second battery banks 20 and 30 at the start of charging control. In this case, control device 50 specifies the SOCs of first and second battery banks 20 and 30 at the end of the charging of battery bank unit 1 as 100%.

In addition, first and second battery banks 20 and 30 are configured similarly to each other as described above, and the environments (temperature and humidity and the like) around first and second battery banks 20 and 30 are approximately equal. Therefore, the time during which charging stops in the second bank charge processing (the time from time t4 to time t5 in FIG. 5) can be regarded as equal to the time during which charging stops in the first bank charge processing (the time from time t2 to time t3). Therefore, in the experiment to determine the total charging time to be stored in first table T1, when battery bank unit 1 has m battery banks, the sum of the times—during each time, charging of any of those battery banks is stopped—is a value obtained by multiplying m by the charging stop time (Ts). In other words, “m×Ts” in Equation (1) corresponds to the sum of the times—during each time, charging of any of those battery banks is stopped—during the charging of battery bank unit 1.

As already described, during the time period in which the charging is stopped in the charging control of battery bank unit 1, discharging from the battery bank (in which charging is stopped) to load device 3 is not performed. For example, between time t2 and time t3 in FIG. 5, discharging from first battery bank 20 is not performed. Therefore, it is not possible to calculate the SOC of the battery bank (in which charging is stopped) based on the detected value of current sensor 60. That is, control device 50 cannot use the SOC to calculate the time during which charging is stopped during charging control of battery bank unit 1.

In Equation (1), “(Tt−m×Ts)” corresponds to the time obtained by subtracting the sum of the times (m×Ts)—during each time, charging of any of those battery banks is stopped—from the total charging time (Tt) in an experiment to determine the total charging time to be stored in first table T1 using a battery bank unit 1 with m battery banks. In other words, “(Tt−m×Ts)” in Equation (1) corresponds to the time during which any of the battery banks is being charged out of the time required for the SOC of battery bank unit 1 with m battery banks to go from α to 100%.

In addition, “(100−So)/(100−α)” in Equation (1) is the ratio of the charge amount for the SOC of battery bank unit 1 to go from So to 100% to the charge amount for the SOC to go from α to 100%.

Therefore, “(Tt−m×Ts)×(100−So)/(100−α)” in Equation (1), which is the product of “(Tt−m×Ts)” and “(100−So)/(100−α)”, corresponds to the time during which any of the battery banks is being charged out of the time required for the SOC of battery bank unit 1 with m battery banks to go from So to 100%.

That is, out of the time required for the SOC of battery bank unit 1 with m battery banks to go from So to 100%, the time during which any of the battery banks is being charged “(Tt−m×Ts)×(100−So)/(100−α)” and the total time during which charging of any battery bank is stopped “m×Ts” are added together in Equation (1). In other words, in the charging control, Equation (1) is an equation for calculating the time from the start of charging to the completion of charging of battery bank unit 1 as the remaining time at the start of charging when the SOC is So at the start of charging control for a battery bank unit 1 with m battery banks.

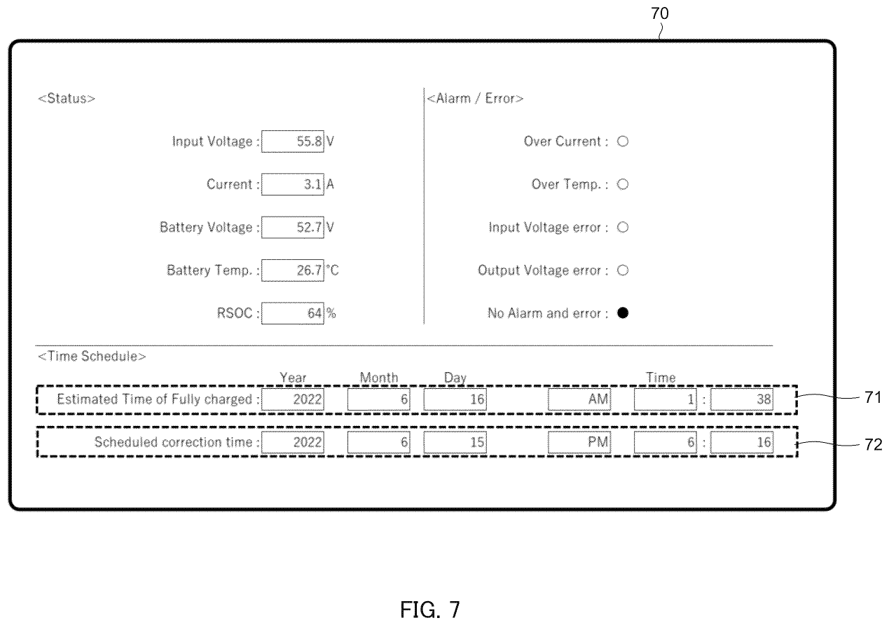

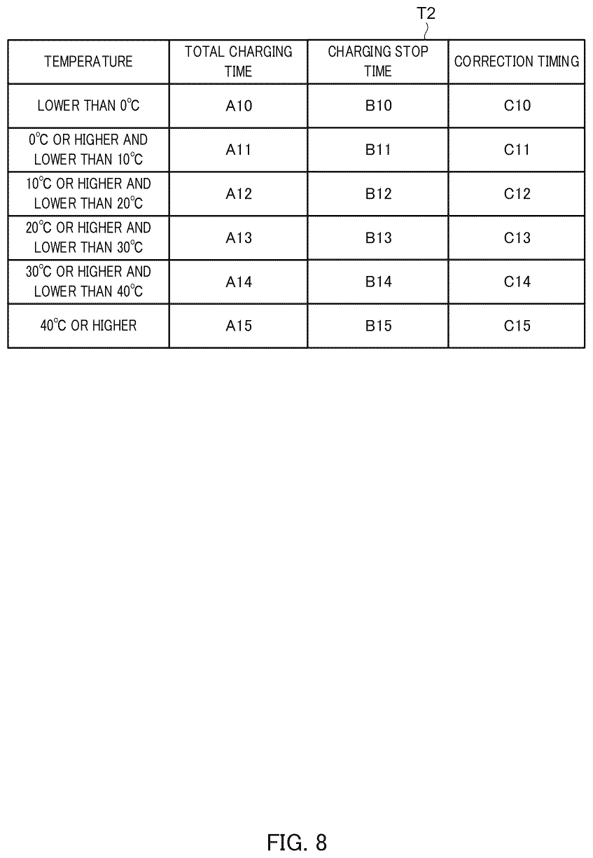

In addition, in S21, control device 50 notifies a user's terminal device (not illustrated) managing load device 3 of the calculated remaining time at the start of charging. The terminal device displays notification screen 70 (see FIG. 7) indicating the remaining time at the start of charging on a display section such as a display. This allows an administrator of load device 3 to understand the time from the start of charging to the completion of charging of battery bank unit 1. Notification screen 70 may display the remaining time at the start of charging as is, or the notification screen may display the estimated charging completion time calculated based on the remaining time at the start of charging. When the remaining time at the start of charging is displayed as the estimated charging completion time, the terminal device may convert the remaining time at the start of charging notified by control device 50 into the estimated charging completion time, or control device 50 may convert the remaining time at the start of charging into the estimated charging completion time and notify the terminal device of the estimated charging completion time. The estimated charging completion time is displayed in estimated charging completion time display section 71 on notification screen 70 illustrated in FIG. 7, for example.

Furthermore, control device 50 measures the elapsed time from the start of charging of battery bank unit 1 during charging control. Then, control device 50 calculates the remaining time at that point by subtracting the elapsed time from the remaining time at the start of charging calculated in S21 at predetermined intervals, updates the latest remaining time, and notifies the terminal device of the updated remaining time. The terminal device displays the updated remaining time on the display section.

In addition, in S21, control device 50 notifies the terminal device of the correction timing information that is read and acquired from first table T1. Correction timing information is information indicating the correction timing, which is the timing at which the calculated value of the remaining time is corrected. For example, the correction timing is expressed as the time interval from the start of charging to the execution of the correction. The terminal device displays notification screen 70 indicating the correction timing information along with the remaining time at the start of charging on the display section. This allows the administrator of load device 3 to understand the timing at which the remaining time is corrected. The display format of the correction timing on notification screen 70 may display how many minutes (or hours) after the current time the correction of the remaining time will be executed, or it may display the scheduled time (scheduled correction time) at which the correction of the remaining time will be executed. When the correction timing is displayed as the scheduled correction time, the terminal device may convert the correction timing notified by control device 50 into the scheduled correction time, or control device 50 may convert the correction timing into the scheduled correction time and notify the terminal device of the scheduled correction time. The scheduled correction time is displayed on notification screen 70 illustrated in FIG. 7 in the scheduled correction time display section 72, for example.

Subsequently, control device 50 determines whether the first bank charge processing has ended in S22. When the collective charge processing or the first bank charge processing is being executed (NO in S22), control device 50 continues the update and notifying of the remaining time. In addition, during the execution of S22, control device 50 measures the times actually required for the collective charge processing and the first bank charge processing (hereinafter referred to as actual collective charging time and actual first bank charging time), respectively.

When the first bank charge processing has ended (YES in S22), control device 50 determines in S23 whether correction of the remaining time at the point when the first bank charge processing ended, i.e., at time t3 in FIG. 5, is necessary. Control device 50 determines that correction of the remaining time at time t3 is necessary when the time difference—the difference between the remaining time at the start of charging calculated in S21 and the corrected remaining time at the start of charging to be described below—is equal to or greater than a predetermined time difference.

The corrected remaining time at the start of charging is the time from the start of charging to the completion of charging of battery bank unit 1, calculated based on the time actually required to the end of the first bank charge processing during charging control. The times required to charge the plurality of battery banks are approximately equal when the plurality of battery banks are configured similarly to each other. Therefore, the actual first bank charging time and the actual time required for the second bank charge processing are approximately equal. In the present embodiment, the corrected remaining time at the start of charging is the sum of the actual collective charging time and twice the actual first bank charging time. When the number of battery banks is m, the corrected remaining time at the start of charging is the sum of the actual collective charging time and m times the actual first bank charging time.

When the time difference is smaller than the predetermined time difference (NO in S23), control device 50 does not correct the remaining time at time t3. On the other hand, when the time difference is equal to or higher than the predetermined time difference (YES in S23), control device 50 corrects the remaining time at time t3 in S24. To be more specific, control device 50 replaces the remaining time at time t3 (at the end of the first bank charge processing) with the actual first bank charging time. In addition, when control device 50 corrects the remaining time at time t3, the control device updates the latest remaining time as follows. After time t3, at predetermined intervals, control device 50 calculates the remaining time at that point by subtracting a time elapsed from time t3 from the actual first bank charging time, and updates the latest remaining time. Then, control device 50 notifies the terminal device of the updated remaining time.

First and second battery banks 20 and 30 are configured similarly to each other as described above, and the surrounding environments (temperature and humidity and the like) around first and second battery banks 20 and 30 are approximately equal. Therefore, the actual time required for the second bank charge processing is approximately equal to the actual first bank charging time. In other words, control device 50 can accurately correct the remaining time by replacing the remaining time with the actual first bank charging time at the point when the first bank charge processing ends, and notify the corrected remaining time. Control device 50 may correct the remaining time in S24 without determining whether correction of the remaining time is necessary in S23.

Therefore, in S24, control device 50 notifies the terminal device of the correction value (updated remaining time) of the calculated value of remaining time. The timing at which this correction is executed is, as described above, notified in advance from control device 50 to the terminal device in S21. Therefore, the user can understand correction timing at the start of charging—the correction timing at which a more accurate remaining time can be obtained—and can promptly check the remaining time through notification screen 70 when the correction timing arrives. That is, according to the present embodiment, the user can understand a more accurate remaining time earlier. In general, the charging curve in charging control (e.g., the fluctuation curve of the voltage values of first and second battery banks 20 and 30 illustrated in FIG. 5) is nonlinear, making it difficult to provide the user with a completely accurate charging completion time at the start of charging. In the present embodiment, at the start of charging, instead of providing a completely accurate charging completion time at the start of charging, the correction timing—at which the estimated charging completion time becomes more accurate than at the start of charging—is notified in S21. Such a configuration enables the user to understand the accurate charging completion time without delay, thereby improving the user convenience.

Subsequently, control device 50 determines whether the second bank charge processing has ended in S25. When the second bank charge processing is being executed (NO in S25), control device 50 continues the update and notifying of the remaining time.

When the second bank charge processing is ended (YES in S25), control device 50 updates first table T1 in S26. Control device 50 updates the total charging time, corresponding to the temperature at the start of charging of battery bank unit 1, in first table T1 based on the actual total charging time. In the charging control, the actual total charging time is the time actually required from the start of charging of battery bank unit 1 to the completion of charging of battery bank unit 1.

To be more specific, control device 50 calculates the updated total charging time by subtracting the remaining time at the start of charging calculated in S21 from the total charging time acquired in S20, and adding the actual total charging time to the subtracted time. In other words, the updated total charging time is obtained as follows: a time (actual total charging time) actually acquired for charging from the SOC (So) at the start of charging to 100% is added to a time for charging from the first charge rate (α) to the SOC (So) at the start of charging. Here, the first charge rate (α) is calculated by subtracting the remaining time at the start of charging calculated in S21 from the total charging time acquired in S20. In other words, the updated total charging time is the time obtained as follows: a total charging time stored in first table T1 is corrected using the difference between the actual measured time (actual total charging time) from the start to the completion of charging of battery bank unit 1 in the charging control and the calculated value (remaining time at the start of charging calculated in S21).

Control device 50 updates the total charging time in first table TI corresponding to the temperature at the start of charging of battery bank unit 1 with the calculated updated total charging time. For example, when the temperature of battery bank unit 1 is 25° C. at the start of charging control, control device 50 updates the total charging time “A3” corresponding to the temperature “20° C. or higher and lower than 30° C.” in first table T1 with the calculated updated total charging time.

Furthermore, control device 50 updates the charging stop time corresponding to the temperature of battery bank unit 1 at the start of charging of battery bank unit 1 in first table T1 with the actual charging stop time. In the charging control, the actual charging stop time is the time that actually elapsed from the stop of charging of first battery bank 20 to the start of charging of second battery bank 30. That is, the charging stop time stored in first table T1 is updated with the time during which charging is actually stopped in the first bank charge processing.

For example, when the temperature of battery bank unit 1 is 25° C. at the start of charging of battery bank unit 1, control device 50 updates the charging stop time “B3” corresponding to the temperature “20° C. or higher and lower than 30° C.” in first table T1 with the actual charging stop time.

Furthermore, control device 50 updates the correction timing in first table T1 corresponding to the temperature of battery bank unit 1 at the start of charging of battery bank unit 1 with the actual correction timing. In the charging control, the actual correction timing is the time interval that actually elapsed from the timing when charging was started to the timing when correction was executed in the charging control.

For example, when the temperature of battery bank unit 1 is 25° C. at the start of charging of battery bank unit 1, control device 50 updates the correction timing “C3” corresponding to the temperature “20° C. or higher and lower than 30° C.” in first table T1 with the actual correction timing.

The actual total charging time, the actual charging stop time, and the actual correction timing vary depending on the environment around battery bank unit 1, the power source voltage value, the temperatures of first and second battery banks 20 and 30, the aging of battery bank unit 1, and the degrees of deterioration of first and second battery banks 20 and 30 (hereinafter referred to as the environment around battery bank unit 1 and the like). Therefore, by updating first table T1 with the updated total charging time, the actual charging stop time, and the actual correction timing, the values stored in first table TI can be made to correspond to the environment around battery bank unit 1 and the like. Each time the charging of first and second battery banks 20 and 30 is executed, control device 50 updates first table T1 in such a way that first table TI corresponds to changes in the environment around battery bank unit 1 and the like. In this manner, the remaining time can be accurately calculated when the charging control is executed, and the reliability of the notification can be improved.

Upon updating of first table T1 in S26, control device 50 ends the control for calculating the remaining time. Control device 50 also ends the notification of the remaining time. When a power outage of external power source 2 occurs during the charging control of battery bank unit 1 and at least one of first and second battery banks 20 and 30 discharges, control device 50 ends the control for calculating the remaining time without updating first table T1.

Although the embodiment of the present disclosure has been specifically described above, the present disclosure is not limited to the specific embodiment described above. Various modifications and changes can be made to the specific examples described in the above embodiment within the scope of the gist of the present disclosure described in the claims.

For example, storage 51 may store plurality of tables. The following describes a case where storage 51 further stores second table T2 illustrated in FIG. 7. In second table T2, the temperature, total charging time, charging stop time, and correction timing are associated with each other in the same manner as first table T1. Second table T2 differs from first table T1 in the values stored in the total charging time, charging stop time, and correction timing.

For calculating the remaining time at the start of charging during charging control, control device 50 selects the table, from which information is to be acquired, from the first and second tables T1 and T2 based on the SOC at the start of charging of battery bank unit 1. To be more specific, when the SOC at the start of charging of battery bank unit 1 is lower than a predetermined second charge rate (e.g., 90%), control device 50 selects first table T1. On the other hand, when the SOC at the start of charging of battery bank unit 1 is equal to or higher than the second charge rate, control device 50 selects second table T2. The second charge rate is an arbitrary value determined based on the characteristics during charging of battery bank unit 1, which will be described below.

For example, when the SOC of battery bank unit 1 is lower than the second charge rate (90%), such as 20%, at the time of connecting battery bank unit 1 to external power source 2 to start charging control, control device 50 selects first table T1.

On the other hand, when battery bank unit 1 is connected to external power source 2 and load device 3, the SOC of battery bank unit 1 decreases due to natural discharge and the like, even when a power outage of external power source 2 does not occur. In a case where it is determined that charging control is started when the SOC of battery bank unit 1 decreases to 90%, control device 50 selects second table T2 based on the SOC at the start of charging control being equal to or higher than the second charge rate (90%).

The SOC of a battery bank affects characteristics such as the rate of increase in voltage and temperature of the battery bank during charging. Therefore, when the SOC of battery bank unit 1 at the start of charging varies, the characteristics during charging (such as the rate of increase of the bank voltage value of battery bank unit 1 per unit time and the rate of increase of the temperature of battery bank unit 1 per unit time) vary, and the rate of increase in charge rate varies. Therefore, control device 50 can accurately calculate the remaining time by selecting an appropriate table based on the SOC of battery bank unit 1 at the start of charging.

In addition, first and second battery banks 20 and 30 may be configured to be different from each other. In this case, the charging stop time in the first bank charge processing, the second charging stop time in the second bank charge processing, the temperature, and the total charging time may be associated with each other in first and second tables T1 and T2. The second charging stop time corresponds to the time during which charging is stopped in the second bank charge processing in the experiment that determines the total charging time to be stored in first table T1.

In addition, when first and second battery banks 20 and 30 are configured to be different from each other, the charging stop time and the second charging stop time cannot be considered equal. In this case, “m×Ts” in Equation (1) is replaced with an expression that adds the charging stop time with the second charging stop time stored in the table when the number of battery banks is two.

In addition, when first and second battery banks 20 and 30 are configured to be different from each other, the following is also possible: the remaining time is not corrected at the end of the first bank charge processing, i.e., S23 and S24 in FIG. 6 are not executed.

In addition, in the charging control, control device 50 may execute the first bank charge processing and the second bank charge processing without performing the collective charge processing. In this case, S1 and S2 in FIG. 4 are not executed, and the actual collective charging time is zero in the calculation of the corrected remaining time at the start of charging.

In addition, battery bank unit 1 may be configured to allow first and second battery banks 20 and 30 to be detachable. In addition, battery bank unit 1 does not have to include first and second battery banks 20 and 30 as its own components. In other words, battery bank unit 1 may be configured to include input/output terminal 10, charge/discharge circuit 40, control device 50, and sensors 60 to 64. In this case, by retrofitting separately arranged first and second battery banks 20 and 30, battery bank unit 1 can function as a backup device for external power source 2.

In addition, storage 51 may be configured separately from control device 50 and be capable of communicating with control device 50. In this case, storage 51 may be communicably connected to control device 50 via a network such as the Internet. By configuring in this manner, information in a table can be shared among plurality of battery bank units 1, and furthermore, the table can be updated so as to store more accurate information by the plurality of battery bank units 1. Moreover, control device 50 may be configured separately from battery bank unit 1. In this case, control device 50 can remotely control battery bank unit 1 and calculate the remaining time via a network such as the Internet.

### Additional Note

To summarize the disclosure of the present embodiment, it is as follows.

### Additional Note 1

Control device 50, namely a charging control device, includes the following: processor 52 that corrects, during the execution of charging of first and second battery banks 20 and 30, a calculated value of a remaining charging time that is calculated at the start of charging of the first and second battery banks 20 and 30, and acquires, at the start of charging, information indicating correction timing at which the calculated value of the remaining charging time is corrected; and notification section 53 that notifies, at the start of charging, the correction timing and notifies, during the execution of the charging, a correction value for the calculated value of the remaining charging time.

According to the above configuration, a user can understand the correction timing that provides a more accurate remaining time at the start of charging, so when the correction timing arrives, the user can promptly confirm the corrected remaining time. In other words, the user can understand a more accurate remaining time earlier.

### Additional Note 2

In the configuration described in additional note 1, control device 50 further includes storage 51 that stores tables (T1 and T2) containing information indicating the correction timing, in which processor 52 reads the correction timing from the tables (T1 and T2) at the start of charging, and notification section 53 notifies the read correction timing.

According to the above configuration, by referring to the table to acquire the correction timing, the effect of additional note 1 can be realized without significantly increasing the load on the processor.

### Additional Note 3

In the configuration described in additional note 2, the tables (T1 and T2) indicate the correction timing for each of reference values (temperature zones) of the temperature of first and second battery banks 20 and 30, namely an energy storage device, and processor 52 reads, from the tables (T1 and T2), the correction timing corresponding to the temperature of first and second battery banks 20 and 30 at the start of charging.

According to the above configuration, different correction timings can be stored individually based on the temperature of the energy storage device, so even when the temperature of the energy storage device fluctuates, the reliability of the notified correction timing can be ensured.

### Additional Note 4

In the configuration described in additional note 2, processor 52 updates the correction timing in the tables (T1 and T2) based on the correction record (actual correction timing) of the calculated value of the remaining charging time.

According to the above configuration, the contents of the table can be adapted to the surrounding environment where the energy storage device is installed, thereby further improving the reliability of the notified correction timing.

### Additional Note 5

Battery bank unit 1, namely an energy storage system, includes control device 50 described in additional note 1, and first and second battery banks 20 and 30.

According to the above configuration, an energy storage system that realizes the effect of additional note 1 can be provided.

### Additional Note 6

A remaining charging time notification method to be executed in control device 50 that, during the execution of charging of first and second battery banks 20 and 30, corrects a calculated value of a remaining charging time calculated at the start of charging of first and second battery banks 20 and 30 and notifies the corrected calculated value (S24), the method including acquiring (S20), at the start of charging, information indicating correction timing at which the calculated value of the remaining charging time is corrected; and notifying, at the start of charging, of the correction timing (S21).

According to the above configuration, a remaining charging time notification method that realizes the effect of additional note 1 can be provided.

### Additional Note 7

A remaining charging time notification program causes a computer to execute the remaining charging time notification method described in additional note 6.

According to the above configuration, a remaining charging time notification program that realizes the effect of additional note 1 can be provided.

The disclosure of Japanese Patent Application No. 2022-167597, filed on Oct. 19, 2022, including the specification, drawings, and abstract, is incorporated herein by reference in its entirety.

### INDUSTRIAL APPLICABILITY

The present invention is suitably used as a battery bank unit.

### REFERENCE SIGNS LIST

1 Battery bank unit
2 External power source
3 Load device
4 Power line
10 Input/output terminals
20 First battery bank
30 Second battery bank
40 Charge/discharge circuit
41 Boost DC/DC converter
42 Changeover switch
43 First charge switch
44 First discharge switch
45 Second charge switch
46 Second discharge switch
50 Control device
51 Storage
52 Processor
53 Communication section
60 Current sensor
61 First voltage sensor
62 First temperature sensor
63 Second voltage sensor
64 Second temperature sensor
70 Notification screen
71 Estimated charging completion time display section
72 Scheduled correction time display section
T1 First table
T2 Second table

1. A charging control device comprising:
a processor that corrects, during an execution of charging of an energy storage device, a calculated value of a remaining charging time calculated at a start of the charging of the energy storage device, and acquires, at the start of the charging, information indicating correction timing at which the calculated value of the remaining charging time is corrected; and
a notification section that notifies, at the start of the charging, the correction timing, and notifies, during the execution of the charging, a correction value for the calculated value of the remaining charging time.

2. The charging control device according to claim 1, further comprising:
a storage that stores a table containing information indicating the correction timing, wherein
the processor reads the correction timing from the table at the start of the charging, and
the notification section notifies the read correction timing.

3. The charging control device according to claim 2, wherein:
the table indicates the correction timing for each of reference values of a temperature of the energy storage device; and
the processor reads, from the table, the correction timing corresponding to the temperature of the energy storage device at the start of the charging.

4. The charging control device according to claim 2, wherein
the processor updates the correction timing in the table based on a correction record of the calculated value of the remaining charging time.

5. An energy storage system comprising:
the charging control device according to claim 1; and
the energy storage device.

6. A remaining charging time notification method to be executed in a charging control device that, during an execution of charging of an energy storage device, corrects a calculated value of a remaining charging time calculated at a start of the charging of the energy storage device and notifies the corrected calculated value, the method comprising:
acquiring, at the start of the charging, information indicating correction timing at which the calculated value of the remaining charging time is corrected; and
notifying, at the start of the charging, the correction timing.

7. A remaining charging time notification program for causing a computer to execute the remaining charging time notification method according to claim 6.
